(19) United States
(12) Patent Application Publication
(10) Pub. No.: US 2013/0032195 A1
(43) Pub. Date: Feb. 7, 2013

(54) PHOTOVOLTAIC MODULE WITH SERIALLY CONNECTED SOLAR CELLS

(71) Applicants: Cheng-Yu Peng, Taoyuan County (TW); Chung-Teng Huang, Taichung City (TW); Fu-Ming Lin, Hsinchu County (TW)

(72) Inventors: Cheng-Yu Peng, Taoyuan County (TW); Chung-Teng Huang, Taichung City (TW); Fu-Ming Lin, Hsinchu County (TW)

(73) Assignee: INDUSTRIAL TECHNOLOGY RESEARCH INSTITUTE, Hsinchu (TW)

(21) Appl. No.: 13/562,265

(22) Filed: Jul. 30, 2012

(30) Foreign Application Priority Data
Aug. 1, 2011 (TW) 100127210

(51) Int. Cl. H01L 31/052; H01L 31/048; H01L 31/05

(52) U.S. Cl. 136/246; 136/244; 136/251

(57) ABSTRACT

The photovoltaic module includes a string of serially connected solar cells. When the string direction of the serially connected solar cells is an “x” direction, the interval between the two solar cells in the x direction ranges from 4 mm to 6 mm so as to enhance light trapping.

### CROSS-REFERENCE TO RELATED APPLICATION

This application claims the priority benefit of Taiwan application serial no. 100127210, filed on Aug. 1, 2011. The entirety of the above-mentioned patent application is hereby incorporated by reference herein and made a part of this specification.

### TECHNICAL FIELD

The technical field relates to photovoltaic module (solar module) with serially connected solar cells.

### BACKGROUND

A photovoltaic module (solar module) package structure typically includes a glass plate, an encapsulant, a solar cell, an encapsulant, and a back sheet. Recently, a transparent photovoltaic module package structure, which includes a glass plate, an encapsulant, a solar cell, an encapsulant, and a glass plate, is also provided. Although these photovoltaic module package structures offer high strength properties, they often suffer from light losses and their power outputs become considerably lowered.

Various approaches, with the intention of decreasing light losses and improving the light trapping efficiency, are pursued through the adjustments on the structural designs of the high light transparency component or the back sheet. For example, provide a saw-teeth structure facing the cell intervals of the solar cell array in the photovoltaic apparatus, or a high light reflective back sheet with a grooved surface.

These approaches mainly focus on the choices of package materials and the improvement of fabrication techniques, and thus these approaches are time-consuming and complicated.

### SUMMARY

The photovoltaic module includes a string of serially connected solar cells. A direction perpendicular to an extension direction of the string of serially connected solar cells is defined as an x-direction, wherein an interval between the solar cells in the x direction ranges from 4 mm to 6 mm.

A photovoltaic module is further introduced. The photovoltaic module includes a string of serially connected solar cells, and a ratio of an interval area at a periphery of a single solar cell to an area of the single solar cell is between 0.058 to 0.125.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a top view diagram of a photovoltaic module according to an exemplary embodiment of the disclosure.

FIG. 2 is a cross-section of photovoltaic module in FIG. 1 along the cutting line II-II.

FIG. 3 is a top view diagram of a photovoltaic module according to another exemplary embodiment of the disclosure.

FIG. 4 is a power increment curve of experiment 1 and comparative experiment 1.

FIG. 5 is a power decrement curve of experiment 2 and comparative experiment 2.

FIG. 6 is a power increment curve of experiment 4 and comparative experiment 2.

FIG. 7 is a power increment curve of experiment 5 and comparative experiment 2.

### DETAILED DESCRIPTION OF DISCLOSED EMBODIMENTS

Reference now is made to the accompanying drawings to describe the exemplary embodiments and examples of the disclosure. Although the disclosure herein refers to certain illustrated embodiments, it is to be understood that these embodiments are presented by way of example and not by way of limitation. Moreover, the drawings are strictly provided for an illustration purpose, and therefore are drawn generally not with a representation in scale.

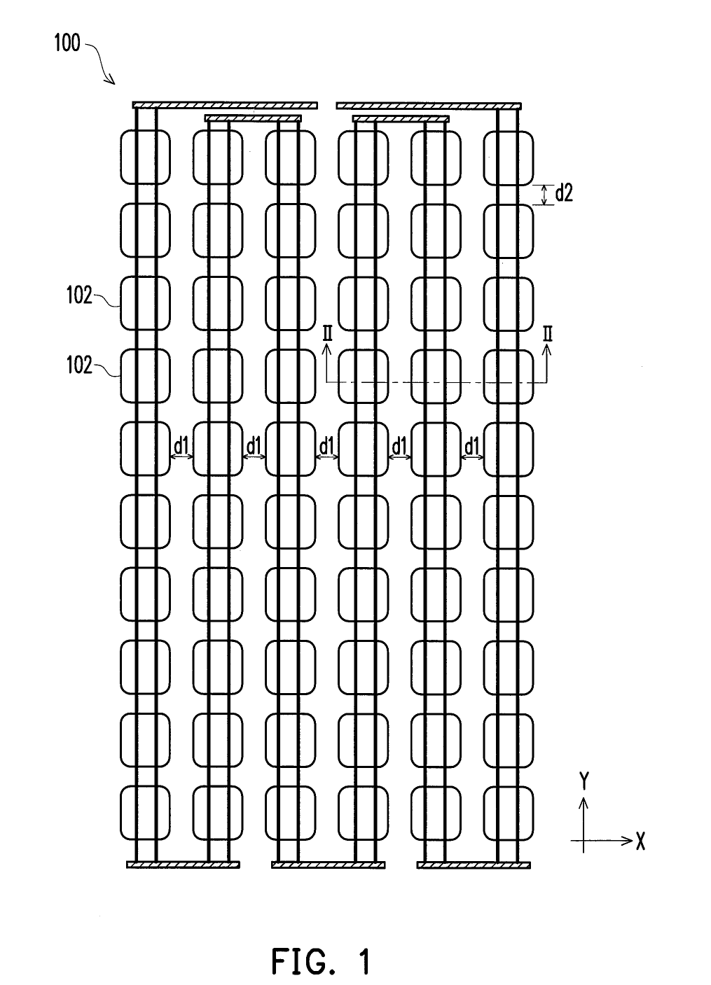

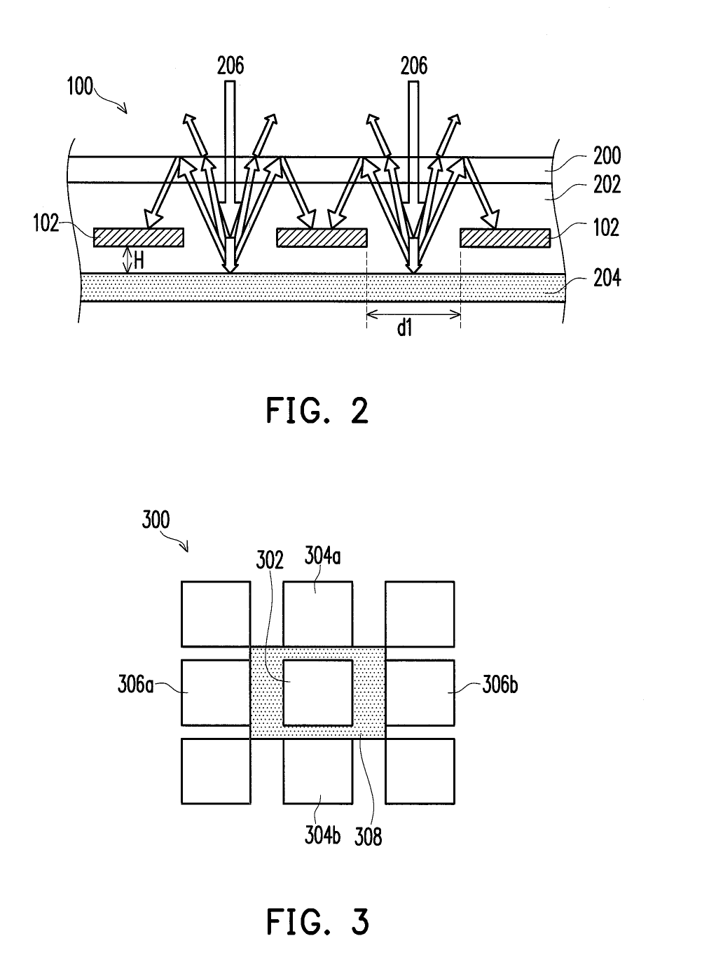

FIG. 1 is a top view diagram of a photovoltaic module according to an exemplary embodiment of the disclosure. FIG. 2 is a cross-section of the photovoltaic module in FIG. 1 along the cutting line II-II.

Referring to FIG. 1, the photovoltaic module 100 of the first exemplary embodiment includes a string of serially connected solar cells 102. The direction, perpendicular to the extension direction of the string of the serially connected solar cells, is defined as the x-direction. The interval d1 between the solar cells in the x-direction ranges from 4 mm to 6 mm. The direction, parallel to the extension direction of the string of serially connected solar cells, is defined as the y-direction. The interval d2 between the solar cells in the y-direction is greater than or equal to 2 mm. It should be noted that the above interval distance between solar cells should not be constructed to limit the scope of the disclosure in any manner.

Referring to FIG. 2, the photovoltaic module 100 of this exemplary embodiment includes a stacked structure of at least a surface layer 200, a string of serially connected solar cells 102, and a back layer 204. An encapsulant 202 encloses the serially connected solar cells 102 and is connected with the surface layer 200 and the back layer 204, respectively. When the material of the back layer 204 is a back sheet, the photovoltaic module 100 is an opaque module. When the material of the back layer 204 is a glass plate, the photovoltaic module 100 is a transparent module. The photovoltaic module 100 may be a back-contact module. The surface layer 200 includes a transparent material, such as glass, ETFE, PVF, or acrylic, or a structure that enhances light scattering. It should be noted that the type photovoltaic module 100 disclosed above should not be constructed to limit the scope of the disclosure in any manner. In the exemplary embodiment, the distance H between the solar cells 102 and the back layer 204 is between 0 mm to about 6.4 mm. It should be noted that the above distance H should not be constructed to limit the scope of the disclosure in any manner.

The material of the surface layer 200 includes glass, polytetrafluoro ethylene (ETFE), polyvinyl fluorite (PVF), or acrylic. The surface layer 200 may include a textured structure.

The material of the back layer 204 includes, but not limited to, glass, ETFE, PVF, or acrylic. The back layer 204 may be a multilayer reflective back layer having a light scattering multilayer surface; for example, a structure is PVDF/PET/PVDF, PA/PA/PA, PVF/PET/PVF, F/PET/PA, PVF/PET/EVA, etc. In view of light-trapping enhancement, because the light scattering multilayer surface possesses zero-depth concentrator effect, this type of material is appropriate as back layer 204. The optical effect thereof is shown in FIG. 2, in which light 206 enters the photovoltaic module 100 and is reflected from the back layer 204 and captured by the solar cells 102. The back layer 204 may include a textured structure to serve as a light scattering surface.

The encapsulant 202 is, for example, a stacked structure. The encapsulant 202 may be selected from at least one of ethylene vinyl acetate copolymer (EVA), polyvinylbutyral (PVB), ETFE, and silicone in the exemplary embodiment.

FIG. 3 is a top view diagram of a photovoltaic module according to another exemplary embodiment of the disclosure. As shown in FIG. 3, the photovoltaic module 300 includes a plurality of solar cells 302, 304a, 304b, 306a, 306b . . . . For the sake of clearer understanding, the elements essential to the implementation of the invention are illustrated in the drawings, while other elements not concerned with the invention are omitted. Enhancing light trapping in the photovoltaic module 300 of the exemplary embodiment is accomplished by controlling the ratio of the margin area 308 (i.e. the dot region depicted in FIG. 3) to the area of the solar cell 302. In particularly, the margin area 308 means a superficial different between the area of the solar cell 302 and a product of a distance between two neighboring solar cell 304a and 304b at opposite side and a distance between two neighboring solar cell 306a and 306b at another opposite side. The ratio of the margin area 308 of the solar cell 302 to the area of single solar cell 302 ranges from 0.058 to 0.125. Other elements, such as the surface layer, the encapsulant, and the back layer of the photovoltaic module 300 may be referred to the photovoltaic module in the first exemplary embodiment as shown in FIG. 2.

The results of several experiments for supporting the effectiveness of the photovoltaic module in the above exemplary embodiments are presented here-below.

### Experiment 1

Five different reflective back layer materials are prepared. These materials, having multi layers of light scattering surface, include A: Krempel AKASOL PVL 1000V (the structure is PVDF/PET/PVDF), B: Isovolta 3554 (the structure is PA/PA/PA), C: Isovolta 2442 (the structure is PVF/PET/PVF), D: Isovolta 3572 (the structure is F/PET/PA), E: Madico TPE (the structure is PVF/PET/EVA).

Thereafter, using 5 different back layers with glass plates, EVA, and a 2×2 array of solar cells, 5 groups of photovoltaic modules are respectively formed, as shown in FIG. 2, wherein each group of photovoltaic module has a structure of glass plate (thickness of 3.2 mm)/EVA (thickness of 0.4 mm)/solar cell (thickness of 0.2 mm)/EVA (thickness of 0.4 mm)/back layer (thickness of 0.2 mm).

Each group of photovoltaic modules includes a cell interval d2 of 2 mm in the y-direction and a distance H of 0.4 mm between the solar cell and the back layer. However, there are 5 different cell intervals d1 in the x-direction: 2 mm, 4 mm, 5 mm, 6 mm, and 10 mm.

### Comparative Experiment 1

Glass plates, EVA, and four solar cells are used to fabricate a group of photovoltaic modules as shown in FIG. 2, wherein each photovoltaic module has a structure of glass plate (thickness of 3.2 mm)/EVA (thickness of 0.4 mm)/solar cell (thickness of 0.2 mm)/EVA (thickness of 0.4 mm)/glass plate (thickness of 3.2 mm).

This group of photovoltaic modules has a cell interval d2 of 2 mm in the y-direction and a distance H of 0.4 mm between the solar cell and the back layer. Similar to Experiment 1, there are 5 different cell intervals d1 in the x-direction: 2 mm, 4 mm, 5 mm, 6 mm, and 10 mm.

### Experiment 2

Back layers, in which the material thereof is B: Isovolta 3554 (the structure is PA/PA/PA), glass plates, EVA, and four solar cells are used to fabricate a group of photovoltaic modules as shown in FIG. 2, wherein each photovoltaic module has a structure of glass plate (thickness of 3.2 mm)/EVA (thickness of 0.4 mm)/solar cell (thickness of 0.2 mm)/EVA (thickness of 0.4 mm)/back layer (thickness of 0.2 mm).

This group of photovoltaic modules includes a cell interval d1 of 4 mm in the x-direction and a distance H of 0.4 mm between the solar cell and the back layer. However, there are 5 different cell intervals d2 in the y-direction: 2 mm, 4 mm, 5 mm, 6 mm, and 10 mm.

### Comparative Experiment 2

Except for replacing the back layer with a glass plate, other components, the interval d1 in the x-direction, the interval d2 in the y direction, and the distance H between the back layer and solar cell are similar to those in Experiment 2.

### Experiment 3

A photovoltaic module is formed with a back layer that constituted with a material of B: Isovolta 3554 (the structure is PA/PA/PA). The structure of the resulting photovoltaic module includes glass plate (thickness of 3.2 mm)/EVA (thickness of 0.4 mm)/solar cell (thickness of 0.2 mm)/EVA (thickness of 0.4 mm)/back layer (thickness of 0.2 mm). The solar cell array is a 6×10 array, and the module is packaged using a single crystalline cell with a conversion efficiency of 18%.

This group of photovoltaic modules includes an interval d2 of 4 mm in the y-direction and a distance H of 0.4 mm between the solar cell and the back layer. There are 5 different intervals d1 in the x-direction: 2 mm, 4 mm, 5 mm, 6 mm, and 10 mm.

### Experiment 4

Except for replacing the glass surface plate with ETFE and using Scotchshield™ Films from 3M™ for the back layer, other components, the interval d1 in the x-direction, the interval d2 in the y direction, and the distance H between the back layer and solar cell are similar to those in Comparative Experiment 2.

### Experiment 5

Except for changing the cell interval d1 in the x-direction to 5 mm and using the material B: Isovolta 3554 (the structure is PA/PA/PA) for the back layer, other components, the cell interval d2 in the y direction, and the distance H between the back layer and solar cell are similar to those in Comparative Experiment 2.

Test Result 1

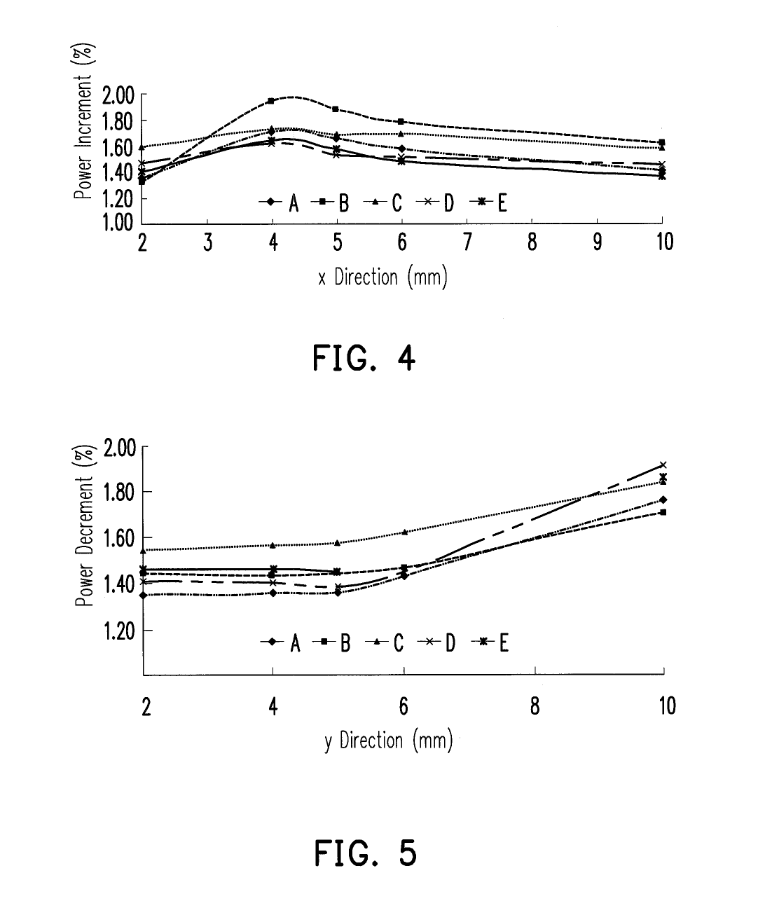

The power outputs of the photovoltaic modules of Experiment 1 and the power outputs of the photovoltaic modules of the Comparative Experiment 1 are estimated by using the A class photovoltaic module flash simulator at standard test conditions (STC). The ratio of the change of the output powers to reference output power is: (power output of Experiment 1−power output of Comparative Experiment 1)/power output of Comparative Experiment 1, and the results are shown in FIG. 4.

As shown in FIG. 4, when the interval d1 in the x-direction is ranged from 4 mm to 6 mm, the power output increment is increased to +1.95% to +1.78%.

Test Result 2

The power output of the photovoltaic modules of Experiment 2 and the power output of the photovoltaic modules of the Comparative Experiment 2 are estimated by using the A class photovoltaic module flash simulator at STC. The ratio of the change of the output powers to reference output power is: (power output of Experiment 2−power output of Comparative Experiment 2)/power output of Comparative Experiment 2, and the results are shown in FIG. 5.

As shown in FIG. 5, when the interval d2 in the y-direction is greater than or equal to 2 mm, the power output decrement is increased to above +0.17% for every 1 mm increase in the cell interval d2 in the y-direction.

Test Result 3

The power output of the photovoltaic modules of Experiment 3 are estimated by using the A class photovoltaic module flash simulator at STC. Comparing the conventional technique, in which the cell interval d1 in the x-direction is 2 mm, with the designs of the exemplary embodiments, in which the cell interval d1 in the x-direction is 4 mm, the power outputs are respectively 273.77 Wp (d1=2 mm) and 246.63 Wp (d1=4 mm). The details of the test results are summarized in Table 1 below.

TABLE 1

| | Isc | Voc | Imp | Vmp | FF | Rs | Rsh | Pmax |
|---|---|---|---|---|---|---|---|---|
| | (A) | (V) | (A) | (V) | (%) | (Ω) | (Ω) | (Wp) |
| d1 = 2 mm | 8.686 | 37.575 | 8.118 | 30.027 | 76.648 | 0.526 | 574.97 | 243.77 |
| d1 = 4 mm | 8.711 | 37.499 | 8.247 | 29.907 | 75.499 | 0.564 | 500.23 | 246.63 |
| d1 = 5 mm | 8.702 | 37.575 | 8.178 | 29.983 | 74.987 | 0.579 | 399.24 | 245.20 |
| d1 = 6 mm | 8.546 | 37.514 | 8.057 | 30.310 | 76.17 | 0.542 | 559.24 | 244.21 |
| d1 = 10 mm | 8.58 | 36.984 | 8.091 | 29.651 | 75.56 | 0.5044 | 739.699 | 239.93 |

The increase of the module efficiency by 1.1% can be calculated from the light trapping efficiency of the cell intervals in Table 1.

Test Results 4

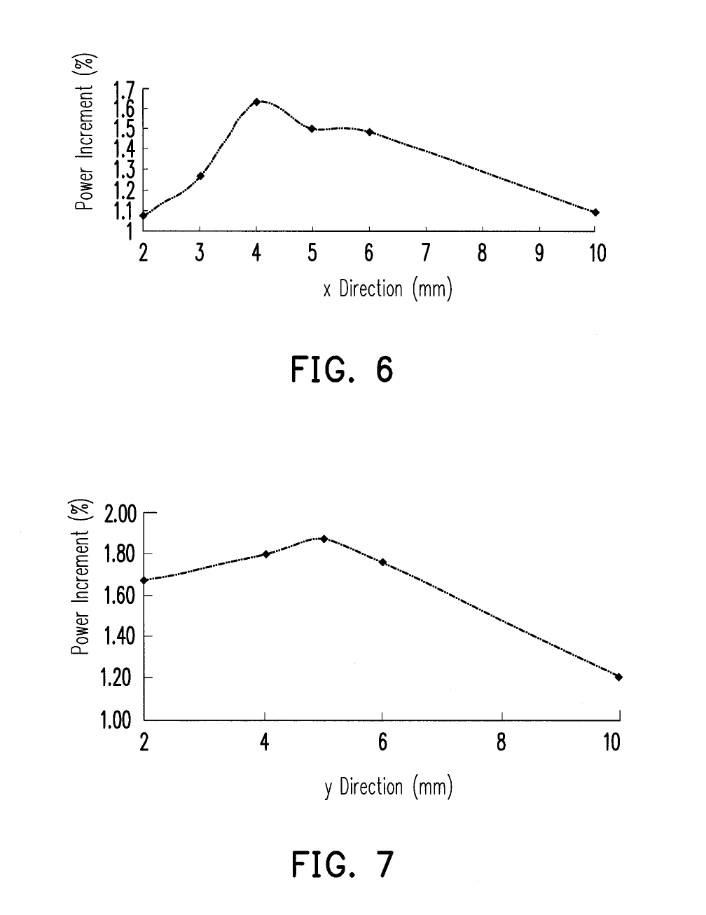

The power output of the photovoltaic modules of Experiment 4 and the power output of the photovoltaic modules of the Comparative Experiment 2 are rated using the A class photovoltaic module flash simulator at STC. The ratio of the change of the output powers to reference output power is: (power output of Experiment 4−power output of Comparative Experiment 2)/power output of Comparative Experiment 2, and the results are shown in FIG. 6.

According to the results as shown in FIG. 6, when a Scotchshield™ film from 3M™ is used for the back layer, the interval d2 in the y-direction is 2 mm, and the distance H between the back layer and solar cell is 0.4 mm, good power increment is achieved for the interval d1, ranging from 4 mm to 6 mm, in the x-direction.

Test Results 5

The power output of the photovoltaic modules of Experiment 5 and the power output of the photovoltaic modules of the Comparative Experiment 2 are rated using the A class photovoltaic module flash simulator at STC. The ratio of the change of the output powers to reference output power is: (power output of Experiment 5−power output of Comparative Experiment 2)/power output of Comparative Experiment 2, and the results are shown in FIG. 7.

According to FIG. 7, when the interval d1 in the x-direction is fixed at 5 mm and the interval d2 in the y-direction is ranged from 2 mm to 10 mm, the power output increment is increased to above +1.2%.

### Experiment 6

When the designs of the commercially available 6 inch (6″) single crystalline and multicrystalline photovoltaic modules are used, the area of the 6″ single crystalline cell is about 239 cm², while the area of the 6″ multicrystalline cell is about 243.36 cm². When a cell interval d1 is 4 mm in the x-direction and a cell intervals d2 in the y-direction is 2 mm, the margin area of the 6″ single crystalline cell is about 23.4 cm², and the margin area of the 6″ multicrystalline cell is about 19.04 cm², and consequentially the ratios of the margin areas of the cells to the areas of the cells are calculated and summarized in Table 2 below.

Similarly, when the designs of the commercially available 6 inch (6″) single crystalline and multicrystalline photovoltaic modules are used, the interval d1 in the x-direction is changed to 6 mm and other conditions remain the same, the ratios of the margin areas of the cells to the areas of the cells are calculated and summarized in Table 2 below.

When an 8 inch (8″) multicrystalline photovoltaic module is used, the area of the 8″ multicrystalline cell is about 20.8×20.8 cm² while the area of the 8″ single crystalline cell is about 432.64 cm². When the interval d2 in the y-direction is 2 mm and the interval d1 in the x-direction are changed to 4 mm and 6 mm, respectively, the ratios of the margin areas of the cells to the areas of the cells are calculated and summarized in Table 2 below.

TABLE 2

| Interval | | Single solar cell | Margin area | |
|---|---|---|---|---|
| between | | area (cm²) | (cm²) | |
| cells | Type of solar cell | A | B | B/A |
| d1 = 4 mm | 6 inch single | 239 | 23.4 | 0.098 |
| d2 = 2 mm | crystalline | | | |
| | 6 inch | 243.36 | 19.04 | 0.078 |
| | multicrystalline | | | |
| | 8 inch single | 428.28 | 20.92 | 0.048 |
| | crystalline | | | |
| | 8 inch | 432.64 | 25.28 | 0.058 |
| | multicrystalline | | | |
| d1 = 6 mm | 6 inch single | 239 | 29.8 | 0.125 |
| d2 = 2 mm | crystalline | | | |
| | 6 inch | 243.36 | 25.44 | 0.105 |
| | multicrystalline | | | |
| | 8 inch single | 428.28 | 29.4 | 0.068 |
| | crystalline | | | |
| | 8 inch | 432.64 | 33.76 | 0.078 |
| | multicrystalline | | | |

Based on the results shown in Table 2, when d1 is in the range of 4 mm to 6 mm, in the application of existing 6 inch solar cell or developing 8 inch solar cell, it may be designed within the range of (margin area of single solar cell)/(area of single solar cell) being equal to 0.058 to 0.125.

According to the above exemplary embodiments, by controlling the interval area of the solar cells, full reflection path can be met in the light guiding design to accomplish light trapping. Further the photovoltaic module is designed with a back layer material possessing the zero-depth concentrator effect, the power output of the photovoltaic module is increased. Moreover, if the photovoltaic module is designed with a textured surface layer, the light diffraction effect is enhanced, which further improves the power output of the module.

Based on the above disclosure, if the light tracing method in the photovoltaic module is applied, full reflection path can be met in the light guiding design if the interval between two solar cells are designed according to the exemplary embodiments of the disclosure. Further, the fabrication method is easy and the power output of the module is enhanced.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A photovoltaic module, comprising:
a string of serially connected solar cells,
wherein a cell interval of the string of serially connected solar cells in an x direction ranges from 4 mm to 6 mm, and the x-direction being perpendicular to an extension direction of the string of serially connected solar cells.

2. The photovoltaic module of claim 1, wherein a cell interval of the string of serially connected solar cells in a y-direction is greater than or equal to 2 mm, and the y-direction is parallel to the extension direction of the string of serially connected solar cells.

3. The photovoltaic module of claim 1, comprising an opaque module, a transparent module, or a back-contact module.

4. The photovoltaic module of claim 1, comprising at least a surface layer, the string of serially connected solar cells, and a back layer to form a stacked structure, and an encapsulant enclosing the string of serially connected solar cells and contacting with the surface layer and the back layer, respectively.

5. The photovoltaic module of claim 4, wherein a material of the surface layer comprises glass, polytetrafluoro ethylene (ETFE), polyvinyl fluorite (PVF), or acrylic.

6. The photovoltaic module of claim 4, wherein the surface layer or the back layer comprises a textured structure.

7. The photovoltaic module of claim 4, wherein a material of the back layer comprises glass, polytetrafluoro ethylene (ETFE), polyvinyl fluorite (PVF), or acrylic.

8. The photovoltaic module of claim 4, wherein the back layer is a multilayer reflective back layer having a light scattering multilayer surface.

9. The photovoltaic module of claim 4, wherein a distance between the string of serially connected solar cells and the back layer is about 0 mm to about 6.4 mm.

10. The photovoltaic module of claim 4, wherein the encapsulant comprises a stacked structure.

11. The photovoltaic module of claim 10, wherein the stacked structure comprises at least one of ethylene vinyl acetate copolymer (EVA), polyvinylbutyral (PVB), ETFE, and silicone.

12. A photovoltaic module, comprising:
a plurality of solar cells,
wherein a ratio of a margin area of each of the solar cells to an area of each of the solar cell ranging from 0.058 to 0.125.

13. The photovoltaic module of claim 12, comprising an opaque module, a transparent module, or a back-contact module.

14. The photovoltaic module of claim 12, comprising at least a surface layer, the solar cells, and a back layer to form a stacked structure, and an encapsulant enclosing the solar cells and contacting with the surface layer and the back layer, respectively.

15. The photovoltaic module of claim 14, wherein a material of the surface layer comprises glass, polytetrafluoro ethylene (ETFE), polyvinyl fluorite (PVF), or acrylic.

16. The photovoltaic module of claim 14, wherein the surface layer or the back layer comprises a textured structure.

17. The photovoltaic module of claim 14, wherein a material of the back layer comprises glass, polytetrafluoro ethylene (ETFE), polyvinyl fluorite (PVF), or acrylic.

18. The photovoltaic module of claim 14, wherein the back layer is a multilayer reflective back layer having a light scattering multilayer surface.

19. The photovoltaic module of claim 14, wherein a distance between the solar cells and the back layer is about 0 mm to about 6.4 mm.

20. The photovoltaic module of claim 14, wherein the encapsulant comprises a stacked structure.

21. The photovoltaic module of claim 20, wherein the stacked structure comprises at least one of ethylene vinyl acetate copolymer (EVA), polyvinylbutyral (PVB), ETFE, and silicone.
